(19) United States
(12) Patent Application Publication
(10) Pub. No.: US 2018/0012541 A1
(43) Pub. Date: Jan. 11, 2018

(54) PHOTO FRAME MODULE

(71) Applicant: PRIMAX ELECTRONICS LTD., Taipei (TW)

(72) Inventor: Yu-Ming Lin, Taipei (TW)

(21) Appl. No.: 15/348,767

(22) Filed: Nov. 10, 2016

(30) Foreign Application Priority Data
Jul. 11, 2016 (TW) 105121756

(51) Int. Cl. G09G 3/30; H05K 7/20; H05K 5/00; G06F 3/02; G09G 5/00; H05K 5/02

(52) U.S. Cl. CPC G09G 3/30; G09G 5/005; H05K 5/0204; H05K 5/0017; G06F 3/0202; H05K 7/20954; G09G 2340/04; G09G 2380/16

(57) ABSTRACT

A photo frame module includes a display device and a fixing structure. The display device includes plural sensing units. When a terminal device is fixed by the fixing structure, a screen of the terminal device is in parallel with the display device. After the terminal device is fixed, an original image shown on the screen of the terminal device is sensed by the plural sensing units, and a sensed image corresponding to the original image is shown on the display device.

### FIELD OF THE INVENTION

The present invention relates to an imaging field, and more particularly to a photo frame module for showing an image.

### BACKGROUND OF THE INVENTION

With increasing development of science and technology, an electronic display device has become a very popular consumer electronic device. The main function of the electronic display device is to output image files. Generally, the image files comprise static electronic files (e.g. photos) and dynamic electronic files (e.g. movies). For example, the electronic display device is a TV set, a computer screen, an electronic photo frame, a digital signage, or the like. As the photos are gradually digitized, the demands on the electronic photo frames gradually increase.

Hereinafter, the structures of a conventional electronic display device will be illustrated with reference to FIGS. 1 and 2. FIG. 1 is a schematic perspective view illustrating the outer appearance of a conventional electronic photo frame. FIG. 2 is a schematic perspective view illustrating the outer appearance of the conventional electronic photo frame of FIG. 1 and taken along another viewpoint. The conventional electronic photo frame 1 comprises a display screen 10, a storage device 11 a connecting slot 12 and a power cable 16. The storage device 11 is disposed within the electronic photo frame 1 for storing image files. The connecting slot 12 is located at a lateral 14 of the electronic photo frame 1. When a memory card 15 for storing image files is inserted into the connecting slot 12, the memory card 15 is accommodated within the connecting slot 12. The display screen 10 is disposed on a front surface 13 of the electronic photo frame 1. Moreover, the display screen 10 is in communication with the storage device 11 and the connecting slot 12. After the power cable 16 is connected with a power source and the electronic photo frame 1 is electrically powered, the image files stored in the storage device 11 or the memory card 15 are shown on the display screen 10.

However, the conventional electronic photo frame 1 still has some drawbacks. For example, for allowing an image file to be continuously shown on the display screen 10, it is necessary to continuously provide electricity to the electronic photo frame 1. That is, the conventional electronic photo frame 1 is neither power-consuming nor environmentally friendly. Therefore, there is a need of providing an improved electronic photo frame.

### SUMMARY OF THE INVENTION

An object of the present invention provides a photo frame module for showing an image without consuming electricity. Consequently, the photo frame module is environmentally friendly.

In accordance with an aspect of the present invention, there is provided a photo frame module. The photo frame module includes a display device and a fixing structure. The display device includes plural sensing units. When a terminal device is fixed by the fixing structure, a screen of the terminal device is in parallel with the display device. After the terminal device is fixed, an original image shown on the screen of the terminal device is sensed by the plural sensing units, and a sensed image corresponding to the original image is shown on the display device.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic perspective view illustrating the outer appearance of a conventional electronic photo frame;

FIG. 2 is a schematic perspective view illustrating the outer appearance of the conventional electronic photo frame of FIG. 1 and taken along another viewpoint;

FIG. 3 is a schematic perspective view illustrating a photo frame module according to an embodiment of the present invention;

FIG. 4 is a schematic exploded view illustrating the display device of the photo frame module of FIG. 3;

FIG. 5 schematically illustrates the operation of the photo frame module of FIG. 3; and

FIG. 6 is a schematic rear view illustrating a photo frame module according to another embodiment of the present invention.

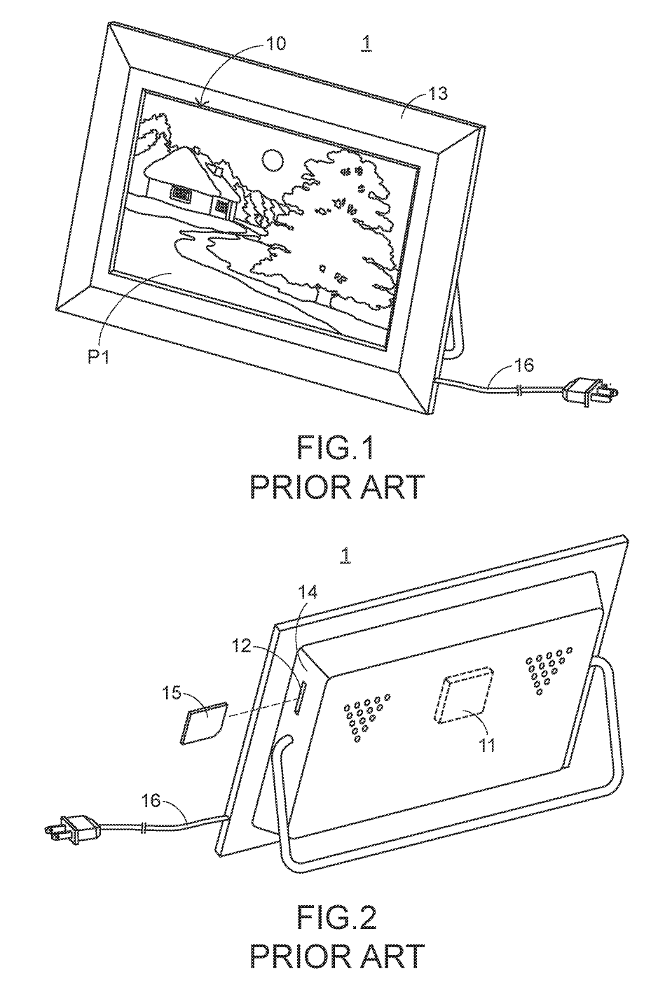

### DETAILED DESCRIPTION OF THE PREFERRED EMBODIMENT

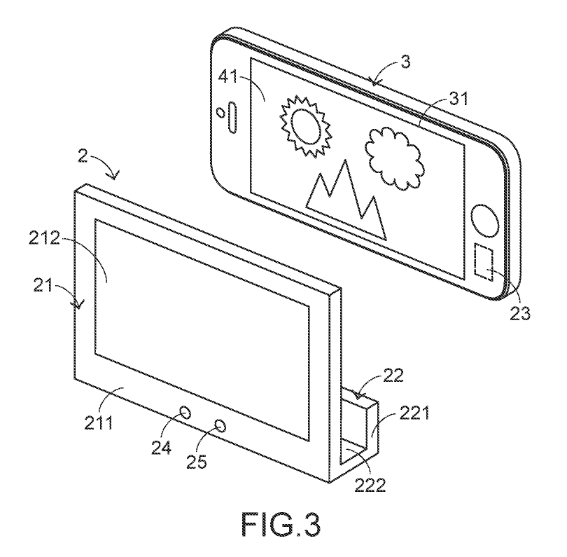

FIG. 3 is a schematic perspective view illustrating a photo frame module according to an embodiment of the present invention. As shown in FIG. 3, the photo frame module 2 comprises a display device 21 and a fixing structure 22. The fixing structure 22 is used for fixing a terminal device 3 and allowing a screen 31 of the terminal device 3 to be in parallel with the display device 21. The fixing structure 22 comprises a base 221. The display device 21 is connected with the base 221. In this embodiment, the display device 21 and the base 221 of the fixing structure are collaboratively defined as a U-shaped structure. An accommodation space 222 is formed between the display device 21 and the base 221. Consequently, the terminal device 3 is disposed and fixed in the accommodation space 222. In an embodiment, the terminal device 3 is a portable electronic device. An example of the portable electronic device includes but is not limited to a mobile phone or a tablet computer.

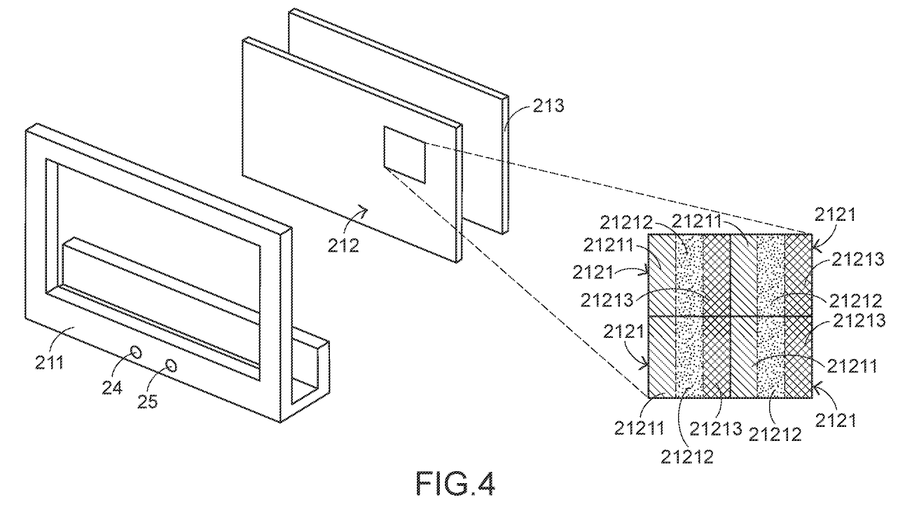

FIG. 4 is a schematic exploded view illustrating the display device of the photo frame module of FIG. 3. As shown in FIG. 4, the display device 21 comprises a frame 211, a display element 212 and a heating element 213. The display element 212 comprises plural sensing units 2121. The plural sensing units 2121 are arranged in an array. Moreover, the display element 212 and the heating element 213 are fixed in the frame 211. For clarification and illustration, only four sensing units 2121 are shown in FIG. 4. In this embodiment, the display element 212 is a thin film display element, and the heating element 213 is a transparent heating plate. The heating element 213 is arranged in front of the display element 212 or behind the display element 212. Moreover, the heating element 213 and the display element 212 are in parallel with each other.

Moreover, each sensing unit 2121 comprises a red light sensing part 21211, a green light sensing part 21212 and a blue light sensing part 21213. Preferably but not restricted, the red light sensing part 21211, the green light sensing part 21212 and the blue light sensing part 21213 are made of phosphor materials. In some other embodiments, the red light sensing part 21211, the green light sensing part 21212 and the blue light sensing part 21213 are made of the light-absorbing materials that absorb light beams of different wavelengths.

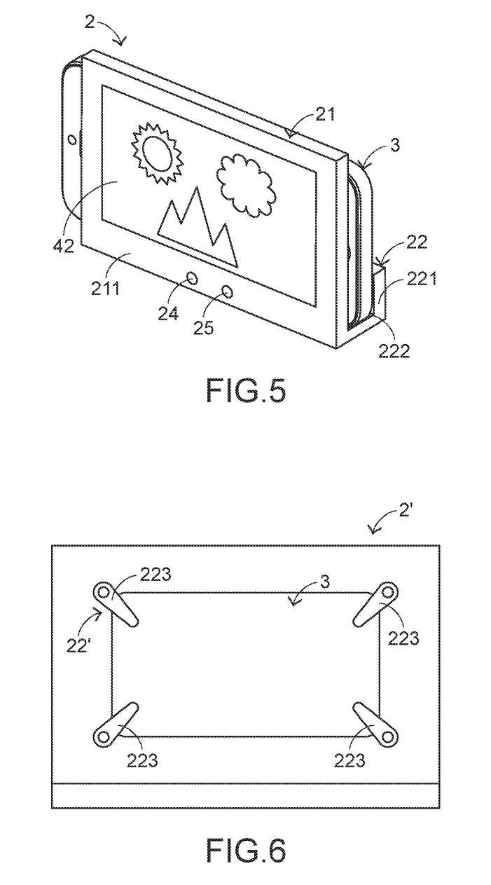

The operations of the photo frame module 2 will be described as follows. FIG. 5 schematically illustrates the operation of the photo frame module of FIG. 3. A process of showing an image by the photo frame module 2 will be described as follows. Firstly, an original image 41 is shown on the screen 31 of the terminal device 3 (see FIG. 3). Then, the terminal device 3 is placed on the base 221, and the terminal device 3 is fixed in the accommodation space 222 between the display device 21 and the base 221. Consequently, the screen 31 of the terminal device 3 is in parallel with the display device 21. After the terminal device 3 is fixed in the accommodation space 222, the light beams from the original image 41 and with different wavelengths are absorbed by the plural sensing units 2121 of the display element 212. Consequently, a sensed image 42 corresponding to the original image 41 is shown on the display element 212. Then, the terminal device 3 is removed from the base 221. In case that the sensing units 2121 of the display element 212 are made of phosphor materials, the sensed image 42 shown on the display element 212 lasts for a certain time period (e.g. more than one day). After the certain time period, the sensed image 42 automatically attenuates and disappears.

If the user wants to change the image shown on the photo frame module 2 before the sensed image 42 shown on the display element 212 automatically attenuates and disappears, the heating element 213 is enabled to provide heat energy to the display element 212. Since the sensing units 2121 of the display element 212 are made of phosphor materials, the sensing units 2121 after heated at a specified temperature (e.g., 65° C.) will be restored to have a transparent color. Meanwhile, the sensed image 42 shown on the display element 212 is deleted. After the sensed image 42 shown on the display element 212 is deleted, the user may perform the above procedures to have the photo frame module to show the desired image.

The example of the heating element 213 is presented herein for purpose of illustration and description only. It is noted that numerous modifications and alterations may be made while retaining the teachings of the invention. For example, in some other embodiments, the heating element is replaced by a heating block (e.g., an electronic eraser) or a heating rod (e.g., an electronic pen) that is individually located outside the display device 21. By using the heating block or the heating rod to wipe the display element 212, the sensed image 42 shown on the display element 212 is deleted.

Preferably but not exclusively, an application program 23 for the photo frame module 2 is installed in the terminal device 3. Before the terminal device 3 is placed on the base 221 of the photo frame module 2, the application program 23 is executed. By executing the application program 23, the resolution of the original image 41 shown on the screen 31 of the terminal device 3 is adjusted to comply with the display resolution suitable for the display device 21. Consequently, the imaging quality of the photo frame module 2 is enabled. Preferably but not exclusively, the resolution of the original image 41 shown on the screen 31 is adjusted to be identical to the display resolution of the display device 21 when the application program 23 is executed. The display resolution of the display device 21 is determined according to the number of the sensing units 2121. For example, in case that the sensing units 2121 are arranged in an A1×A2 array, the display resolution of the display device 21 is A1×A2.

In an embodiment, the photo frame module 2 further comprises an enable switch 24 and a delete switch 25. The enable switch 24 and the delete switch 25 are disposed on the frame 211. After the terminal device 3 is placed on the base 221 of the photo frame module 2, the user may press the enable switch 24 to enable the display element 212. After the display element 212 is enabled, the plural sensing units 2121 of the display element 212 start to sense the original image 41. Moreover, for deleting the sensed image 42 shown on the display element 212, the user may press the delete switch 25 to enable the heating element 213. When the heating element 213 is enabled, the heating element 213 provides heat energy to the display element 212.

It is noted that the examples of the enable switch 24 and the delete switch 25 are not restricted. In another embodiment, the enable switch 24 is disposed on the display element 212, and the delete switch 25 is disposed on the heating element 213. Alternatively, the enable switch 24 and the delete switch 25 are selective items of a user operation interface, which is shown on the screen 31 of the terminal device 3 and provided by the application program 23. Moreover, the enable switch 24 and the delete switch 25 are not essential components of the photo frame module 2.

FIG. 6 is a schematic rear view illustrating a photo frame module according to another embodiment of the present invention. The structures of the photo frame module 2′ of this embodiment that are similar to those of the photo frame module of the above embodiment are not redundantly described herein. In comparison with the above embodiment, the fixing structure 22′ of the photo frame module 2′ of this embodiment is distinguished. The fixing structure 22′ further comprises a clamping part 223. The clamping part 223 is disposed on the frame 211. A process of showing an image by the photo frame module 2′ will be described as follows. Firstly, an original image 41 is shown on the screen 31 of the terminal device 3 (see FIG. 3). Then, the terminal device 3 is fixed on the display device 21 by the clamping part 223. Consequently, the screen 31 of the terminal device 3 is in parallel with the display device 21. The condition that the screen 31 of the terminal device 3 is in parallel with the display device 21 is similar to the condition of FIG. 4.

Similarly, after the terminal device 3 is fixed on the display device 21, the light beams from the original image (see FIG. 4) shown on the screen of the terminal device (see FIG. 4) are absorbed by the plural sensing units of the display element (see FIG. 4). Consequently, a sensed image (see FIG. 4) corresponding to the original image is shown on the display element. Then, the terminal device 3 fixed by the clamping structure 223 is removed. In case that the sensing units of the display element are made of phosphor materials, the sensed image shown on the display element lasts for a certain time period (e.g. more than one day). After the certain time period, the sensed image automatically attenuates and disappears.

From the above descriptions, the present invention provides a photo frame module. The photo frame module comprises the sensing units and the fixing structure. When the display device of the photo frame module is not electrically powered, the sensing units can absorb light beams of different wavelengths. Moreover, when the terminal device is fixed by the fixing structure, the original image shown on the screen of the terminal device is sensed by the display device. For showing an image, it is not necessary to continuously provide electricity to the photo frame module. Consequently, the photo frame module of the present invention is environmentally friendly and industrially valuable.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all modifications and similar structures.

What is claimed is:

1. A photo frame module, comprising:
a display device comprising plural sensing units; and
a fixing structure, wherein when a terminal device is fixed by the fixing structure, a screen of the terminal device is in parallel with the display device,
wherein after the terminal device is fixed, an original image shown on the screen of the terminal device is sensed by the plural sensing units, and a sensed image corresponding to the original image is shown on the display device.

2. The photo frame module according to claim 1, wherein the fixing structure comprises a base, and the display device is connected with the base, wherein an accommodation space is formed between the display device and the base, and the terminal device is disposed and fixed in the accommodation space.

3. The photo frame module according to claim 2, wherein the display device and the base are collaboratively defined as a U-shaped structure.

4. The photo frame module according to claim 1, wherein the display device comprises a frame and a display element, the display element is fixed in the frame, and the plural sensing units are disposed on the display element.

5. The photo frame module according to claim 4, wherein the fixing structure comprises a clamping part, and the clamping part is disposed on the frame.

6. The photo frame module according to claim 4, wherein the display element is a thin film display element.

7. The photo frame module according to claim 1, wherein the photo frame module further comprises a heating element, wherein when the heating element provides heat energy to the plural sensing units, the sensed image shown on the display device is deleted.

8. The photo frame module according to claim 7, wherein the photo frame module further comprises a delete switch, wherein when the delete switch is triggered, the heating element provides the heat energy to the plural sensing units.

9. The photo frame module according to claim 8, wherein the delete switch is disposed on the display device, the fixing structure or the terminal device.

10. The photo frame module according to claim 7, wherein the heating element is a heating plate that is disposed within the display device.

11. The photo frame module according to claim 7, wherein the heating element is a heating block or a heating rod that is individually located outside the display device.

12. The photo frame module according to claim 1, wherein an application program corresponding to the photo frame module is installed in the terminal device, wherein when the application program is executed, a resolution of the original image shown on the screen of the terminal device is adjusted to comply with a display resolution of the display device.

13. The photo frame module according to claim 12, wherein the resolution of the original image is identical to the display resolution of the display device.

14. The photo frame module according to claim 1, wherein a display resolution of the display device is determined according to a number of the sensing units.

15. The photo frame module according to claim 1, wherein each of the plural sensing units comprises a red light sensing part, a green light sensing part and a blue light sensing part.

16. The photo frame module according to claim 1, wherein each of the plural sensing unit contains at least one phosphor material.

17. The photo frame module according to claim 1, wherein the photo frame module further comprises an enable switch, wherein when the enable switch is triggered, the plural sensing units start to sense the original image.

18. The photo frame module according to claim 17, wherein the enable switch is disposed on the display device, the fixing structure or the terminal device.
